(19) United States
(12) Patent Application Publication
(10) Pub. No.: US 2014/0342569 A1
(43) Pub. Date: Nov. 20, 2014

(54) NEAR SURFACE ETCH SELECTIVITY ENHANCEMENT

(71) Applicant: Applied Materials, Inc., Santa Clara, CA (US)

(72) Inventors: Lina Zhu, San Jose, CA (US); Sean S. Kang, San Ramon, CA (US); Srinivas D. Nemani, Sunnyvale, CA (US); Sergey G. Belostotskiy, Santa Clara, CA (US); Jeremiah T. Pender, San Jose, CA (US)

(73) Assignee: Applied Materials, Inc., Santa Clara, CA (US)

(21) Appl. No.: 13/970,481

(22) Filed: Aug. 19, 2013

Related U.S. Application Data
(60) Provisional application No. 61/824,031, filed on May 16, 2013.

(51) Int. Cl. H01L 21/3065

(52) U.S. Cl. CPC H01L 21/3065
USPC 438/710

(57) ABSTRACT

A method of selectively dry etching exposed substrate material on patterned heterogeneous structures is described. The method includes a plasma process prior to a remote plasma etch. The plasma process may use a biased plasma to treat an untreated substrate portion in a preferred direction to form a treated substrate portion. Subsequently, a remote plasma is formed using a fluorine-containing precursor to etch the treated substrate portion using the plasma effluents. By implementing biased plasma processes, the normally isotropic etch may be transformed into a directional (anisotropic) etch despite the remote nature of the plasma excitation during the etch process.

### CROSS-REFERENCES TO RELATED APPLICATIONS

This application claims the benefit of U.S. Prov. Pat. App. No. 61/824,031 filed May 16, 2013, and titled “NEAR SURFACE SILICON ETCH SELECTIVITY ENHANCEMENT” by Zhu et al., which is hereby incorporated herein in its entirety by reference for all purposes.

### FIELD

The present invention relates to semiconductor processing.

### BACKGROUND

Integrated circuits are made possible by processes which produce intricately patterned material layers on substrate surfaces. Producing patterned material on a substrate is enabled by controlled methods for removal of exposed material. Chemical etching is used for a variety of purposes including transferring a pattern in photoresist into underlying layers, thinning layers or thinning lateral dimensions of features already present on the surface. Often it is desirable to have an etch process which etches one material faster than another helping e.g. a pattern transfer process proceed. Such an etch process is said to be selective of the first material relative to the second material. As a result of the diversity of materials, circuits and processes, etch processes have been developed with a selectivity towards a variety of materials.

Dry etch processes are often desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Some dry-etch processes involve the exposure of a substrate to remote plasma by-products formed from one or more precursors. For example, remote plasma generation of nitrogen trifluoride in combination with ion suppression techniques enables silicon to be selectively removed from a patterned substrate when the plasma effluents are flowed into the substrate processing region. However, the silicon selectivity occasionally needs to be even higher for various applications. Additional process flexibility is also desirable.

Methods are needed to increase process flexibility for silicon selective dry etch processes.

### BRIEF SUMMARY

A method of selectively dry etching exposed substrate material on patterned heterogeneous structures is described. The method includes a plasma process prior to a remote plasma etch. The plasma process may use a biased plasma to treat an untreated substrate portion in a preferred direction to form a treated substrate portion. Subsequently, a remote plasma is formed using a fluorine-containing precursor to etch the treated substrate portion using the plasma effluents. By implementing biased plasma processes, the normally isotropic etch may be transformed into a directional (anisotropic) etch despite the remote nature of the plasma excitation during the etch process.

Embodiments of the invention include method of etching a patterned substrate. The method includes treating the patterned substrate with a local plasma formed from an inert gas. Treating the patterned substrate includes treating an untreated substrate portion to form a treated substrate portion. The local plasma is formed by applying a local plasma power to excite the local plasma. The method further includes etching the treated substrate portion. Etching the treated substrate portion comprises flowing plasma effluents into the substrate processing region. The plasma effluents are formed by flowing a fluorine-containing precursor into a remote plasma region fluidly coupled to a substrate processing region housing the patterned substrate while forming a remote plasma in the remote plasma region to produce plasma effluents. The method further includes applying an RF plasma having an RF plasma power to the plasma region.

Embodiments of the invention include methods of etching a patterned substrate having exposed silicon of an untreated silicon portion and exposed dielectric. The method includes treating the patterned substrate with a local plasma formed from an inert gas. Treating the patterned substrate includes treating the untreated silicon portion to form a treated silicon portion and the local plasma is formed by applying a local plasma power. The method further includes flowing a fluorine-containing precursor into a remote plasma region fluidly coupled to a substrate processing region while forming a remote plasma in the remote plasma region to produce plasma effluents. In one embodiment, the method includes applying an RF plasma having an RF plasma power to the plasma region and etching the treated silicon portion by flowing the plasma effluents into the substrate processing region.

Additional embodiments and features are set forth in part in the description that follows, and in part will become apparent to those skilled in the art upon examination of the specification or may be learned by the practice of the embodiments. The features and advantages of the embodiments may be realized and attained by means of the instrumentalities, combinations, and methods described in the specification.

### BRIEF DESCRIPTION OF THE DRAWINGS

A further understanding of the nature and advantages of the embodiments may be realized by reference to the remaining portions of the specification and the drawings.

FIG. 1 is a flow chart of a silicon selective etch process according to embodiments.

FIG. 2A-2D show cross-sectional views of a device at various stages during a silicon selective etch process according to embodiments.

FIG. 3 shows a graph indicative of etch rate during a silicon selective etch process according to embodiments.

FIG. 4A shows a schematic cross-sectional view of a substrate processing chamber according to embodiments.

FIG. 4B shows a schematic cross-sectional view of a portion of a substrate processing chamber according to embodiments.

FIG. 4C shows a bottom plan view of a showerhead according to embodiments.

FIG. 5 shows a top plan view of an exemplary substrate processing system according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

A method of selectively dry etching exposed substrate material on patterned heterogeneous structures is described. The method includes a plasma process prior to a remote plasma etch. The plasma process may use a biased plasma to treat an untreated substrate portion in a preferred direction to form a treated substrate portion. Subsequently, a remote plasma is formed using a fluorine-containing precursor to etch the treated substrate portion using the plasma effluents. By implementing biased plasma processes, the normally isotropic etch may be transformed into a directional (anisotropic) etch despite the remote nature of the plasma excitation during the etch process.

Embodiments of the present invention pertain to selectively remove material from a patterned substrate. The substrate may be silicon, in embodiments, and reference will typically be made herein to a treated or untreated silicon portions for simplicity. In one embodiment, the patterned substrate is subjected to a local plasma treatment to tenderize/weaken a portion of exposed material. Before local plasma treatment, the portion of exposed silicon may be referred to herein as untreated silicon or less treated silicon. After local plasma treatment, the portion of exposed silicon will be referred to as treated silicon. The treated silicon is more rapidly etched during a finite portion of the subsequent process. Next, plasma effluents are generated using remote excitation of a fluorine-containing precursor. The plasma effluents are transferred into a substrate processing region housing the substrate. The plasma effluents react with the exposed silicon portion and preferentially remove the weaken silicon from the patterned substrate. The removal rate of the weakened silicon is greater than the removal rate of untreated (or less treated) silicon as well as silicon oxide, silicon nitride, high-k gate material and other non-silicon materials. Maximizing the etch selectivity, in embodiments, involves terminating the etch process at some point before all weakened/treated silicon is removed. In addition to the increase in removal rate, implementing a local plasma treatment makes the remote plasma etch process directional/anisotropic. The shape of removed silicon may be engineered to suit a variety of device performance goals.

An ion suppression element may be included in the remote etch processes described herein. The ion suppression element functions to reduce or eliminate ionic/charged species traveling from the plasma generation region to the substrate. Uncharged neutral and radical species may pass through the openings in the ion suppressor to react at the substrate. The ion suppressor helps control the concentration of ionic species in the reaction region at a level that increases selectivity.

In accordance with some embodiments of the invention, an ion suppressor as described in the exemplary equipment section may be used to provide radical and/or neutral species for selectively etching substrates. In one embodiment, for example, an ion suppressor is used to provide fluorine-containing plasma effluents to selectively etch silicon. The ion suppressor may be used to provide a reactive gas having a higher concentration of radicals than ions. Because most (or essentially all in embodiments) of the charged particles of a plasma are filtered or removed by the ion suppressor, the substrate is not necessarily biased during the etch process. Such a process using radicals and other neutral species can reduce plasma damage compared to conventional plasma etch processes that include sputtering and bombardment. By filtering ions from the plasma effluents before they reach the substrate processing region, a high etch rate selectivity of silicon relative to silicon oxide, silicon nitride and many alternative materials may be achieved. Embodiments of the present invention are also advantageous over conventional wet etch processes where surface tension of liquids can cause bending and peeling of small features.

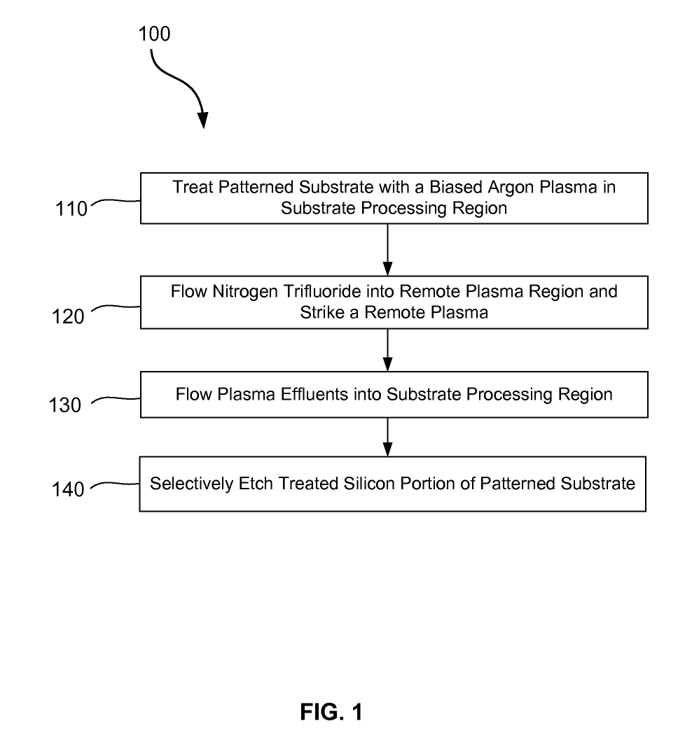

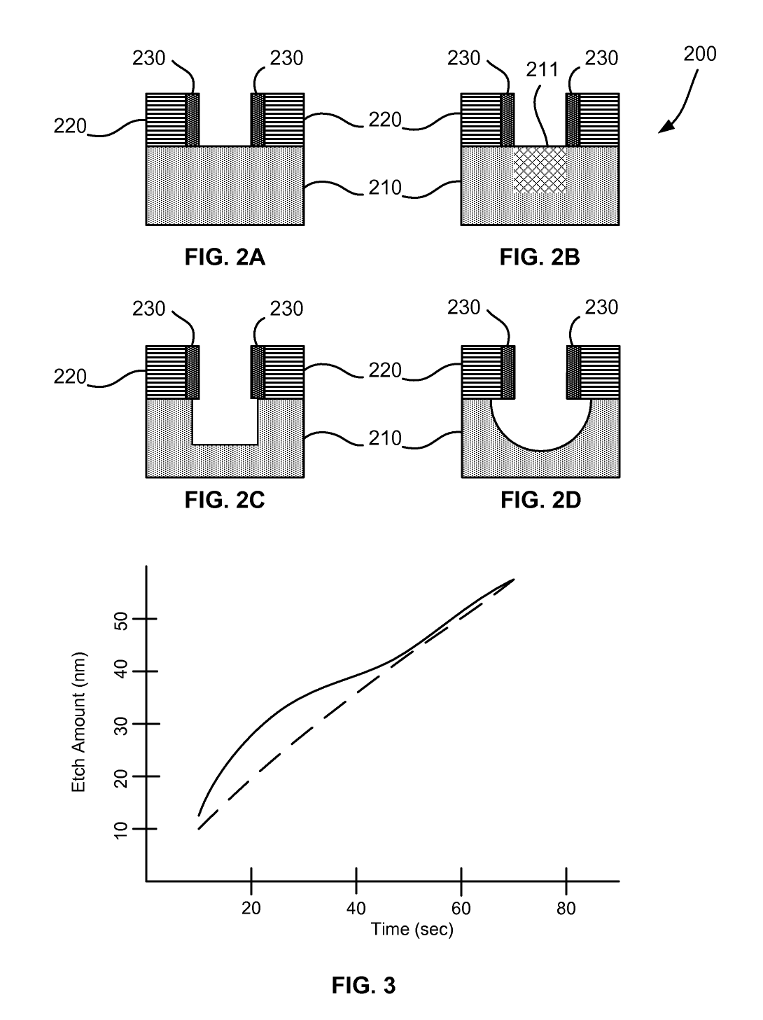

In order to better understand and appreciate embodiments of the invention, reference is now made to FIG. 1 which is a flow chart of an exemplary substrate selective etch process 100 according to embodiments. Cross-sectional views of a device at stages throughout the process may also be useful. Therefore, reference will concurrently be made to FIGS. 2A-2D which show cross-sectional views of an exemplary device during silicon selective etch processes. In one example, a device 200 comprises a patterned substrate 210, silicon nitride 230 and high-k gate 220. A wide variety of other device configurations will also benefit from the selective etch processes described herein. In one embodiment, the substrate is silicon (untreated at the start of etch process 100) and may be single crystalline or polycrystalline (in which case it is usually referred to as polysilicon). Single crystal silicon is shown in the example depicted. Prior to a first operation, a structure is formed in the patterned substrate. The structure possesses separate exposed portions of the substrate 210, silicon nitride 230 and high-k gate 220. In one embodiment, the etch process described below makes way for a silicon germanium deposition which applies a controlled stress to desirably apply stress to the active region of single crystal silicon under high-k gate 220. In other words, the source and drain are recessed into the substrate to make way for a functional secondary material.

The patterned substrate is then delivered into a substrate processing region. Argon is then flowed into the substrate processing region housing the patterned substrate (operation 110). The argon is excited in a local capacitively-coupled plasma within the substrate processing region and the patterned substrate is bombarded with argon ions. A DC voltage may be applied to assist in the acceleration of argon ions toward the patterned substrate and to treat a portion of substrate 210 to form treated substrate portion 211. The substrate processing region may include other elements or the substrate processing region may consist only of argon in embodiments. The substrate processing region may be devoid of reactive species like N₂, O₂ and H₂ to suppress some or any etching of the silicon nitride, or other exposed materials, later in the process. The exemplary argon treatment (operation 110 of etch process 100) weakens the material in a near-surface portion of the exposed substrate, transforming the untreated substrate portion into the treated substrate portion 211. Treated substrate portion 211 may be subsequently etched more easily (at a greater etch rate). The material may be transitioning from polycrystalline or single-crystalline silicon to amorphous silicon during operation 110.

A flow of nitrogen trifluoride is then introduced into a remote plasma region (operation 120 of etch process 100) where the nitrogen trifluoride is excited in a remote plasma struck within the separate plasma region. The separate plasma region may be referred to as a remote plasma region herein and may be within a distinct module from the processing chamber or a compartment within the processing chamber separated from the substrate processing region by a permeable barrier. In general, a fluorine-containing precursor may be flowed into the remote plasma region and the fluorine-containing precursor comprises at least one precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride and xenon difluoride. The remote plasma region may be devoid of hydrogen during operations 120-140 of etch process 100.

Continuing with embodiments of etch process 100, the plasma effluents formed in the remote plasma region are then flowed into the substrate processing region (operation 130) and the patterned substrate is selectively etched (operation 140). The plasma effluents may enter the substrate processing region through through-holes in a showerhead which separates the remote plasma region from the substrate processing region. Treated silicon portion 211 is removed at a higher rate than untreated silicon would etch. The process may be shortened or otherwise modified to reduce aggressiveness as a result of the operation 110 of etch process 100. The rectangular profile in substrate 210 is a result of the directional nature of the treatment in combination with the abbreviated selective etch of operation 140. In the example described here, the rectangular profile is desirable because a silicon germanium plug deposited in a rectilinear cavern applies a more regular and predictable stress on the active silicon region below high-k gate 220. FIG. 2D shows the profile if only operations 120-140 are applied without the treatment (operation 110). The reactive chemical species are removed from the substrate processing region and then the substrate is removed from the processing region.

Generally speaking, the argon used in the exemplary process of FIG. 1 may be any inert gas, where an inert gas contains only atoms (and ions, of course) which do not form covalent bonds in the treated film. The inert gas may include one or more of neon, helium, argon, xenon and the like. The local plasma may consist of inert gases. In embodiments, the inert gas consists of argon, consists of neon or consists of xenon. The inert gas consists of argon, neon and/or xenon in embodiments. The local plasma may consist essentially of inert gases. In some embodiments, the inert gas consists essentially of argon, consists essentially of neon or consists essentially of xenon. The inert gas consists essentially of argon, neon and/or xenon in embodiments. The term “essentially” is added to allow for a minority concentration of other elements which may be present in the substrate processing region, but do not react with exposed substrate portions to a degree which affects the selectivity of etch process 100.

The etch process 100 includes applying energy to the inert gas (e.g. argon) while in the substrate processing region to generate the ions used to treat the substrate (operation 110). The plasma may be generated using known techniques (e.g., radio frequency excitations, capacitively-coupled power, inductively coupled power, and the like). In an embodiment, the energy is applied using a capacitively-coupled plasma unit. The local plasma power may be between about 10 watts and about 500 watts, between about 20 watts and about 400 watts, between about 30 watts and about 300 watts, or between about 50 watts and about 200 watts in embodiments of the invention. Higher powers in combination with higher operating pressures enable a reduction in force of impact of accelerated ions and preserve the integrity of patterned features other than the exposed silicon on the patterned substrate surface.

A DC accelerating voltage may also be applied such that positive ions formed in the local plasma are accelerated in the direction of the patterned substrate. In other words, the local plasma may be formed by applying a DC bias power such that the local plasma power comprises both an AC portion and a DC portion. The DC bias power supplies a DC accelerating voltage which may be greater than 400 volts, greater than 500 volts, greater than 600 volts, or greater than 700 volts in embodiments of the invention. The DC voltage may be less than 2000 volts, less than 1500 volts, less than 1300 volts or less than 1100 volts to preserve the integrity of non-silicon components. The pressure in the substrate processing region may be between about 0.5 mTorr and about 50 mTorr, between about 2 mTorr and about 200 mTorr or between about 5 mTorr and about 100 mTorr in embodiments. The selective substrate etch (operation 140 of etch process 100) may last between 1 second and about 15 seconds.

The etch process 100 also includes applying energy to the fluorine-containing precursor while in the remote plasma region to generate the plasma effluents (operation 120). As would be appreciated by one of ordinary skill in the art, the plasma may include a number of charged and neutral species including radicals and ions. The plasma may be generated using known techniques (e.g., radio frequency excitations, capacitively-coupled power, inductively coupled power, and the like). In an embodiment, the energy is applied using a capacitively-coupled plasma unit. The remote plasma source power may be between about 300 watts and about 5000 watts, between about 500 watts and about 3000 watts, between about 750 watts and about 2000 watts, or between about 900 watts and about 1500 watts in embodiments of the invention. The etch rate has been observed by the inventors to generally increase as RF power is raised from about 300 watts to about 1000 watts, after which the etch rate plateaus. Operating at about 1000 watts or above produces a process which is substantially insensitive to fluctuations in plasma power. Exceeding 1000 watts significantly (e.g. above 1500 watts) does not harm the process, but sacrifices energy efficiency. As with all complementary ranges provided herein, upper limits may be combined with any suitable lower limits to obtain additional embodiments. The pressure in the remote plasma region may be such that the pressure in the substrate processing region ends up between about 0.01 Torr and about 50 Torr or between about 0.1 Torr and about 5 Torr in embodiments. The capacitively-coupled plasma unit may be disposed remote from a gas reaction region of the processing chamber. For example, the capacitively-coupled plasma unit and the plasma generation region may be separated from the gas reaction region by a showerhead.

The RF frequency applied for either the local or remote plasmas described herein may be low RF frequencies less than about 200 kHz, high RF frequencies between about 10 MHz and about 15 MHz, or microwave frequencies greater than or about 1 GHz in embodiments.

A native oxide may be present on exposed portions of silicon which have been exposed to oxygen or the atmosphere. The native oxide can be removed by local plasma processes, remote plasma processes which form sublimatable salts or chemical treatments carried out at atmospheric pressures. Regardless of the method used, the native oxide (if present) may or may not be removed before the operation of treating and etching the exposed silicon. The plasma treatment has been found, in embodiments, to remove (or enable the subsequent removal of) the thin native oxide in addition to treating the exposed silicon portion. Finally, the terms “exposed silicon portion” and “exposed silicon” will be used herein regardless of whether a thin native oxide is present.

The rectangular cavern created by the exemplary etch process 100 was formed by using embodiments of the present invention. The etch process 100 exhibits a pronounced anisotropy in etch rate, in other words, the compound etch removes material more rapidly down into the substrate (FIG. 2) than laterally underneath silicon nitride 230. Embodiments of the present invention enable the production of smaller devices by restricting the lateral incursion while still allowing silicon germanium to be formed within the cavern to create the same beneficial stress profile. In many applications, the trench width may be less than or about 30 nm, less than or about 25 nm, less than or about 20 nm or less than or about 15 nm in embodiments of the invention. These trench widths apply to a variety of applications and transcend the single example discussed herein. The etch processes described herein may remove material vertically faster than laterally by a multiplicative factor greater than or about two, greater than or about three or greater than or about four in embodiments. The patterned substrate may have silicon nitride on both sides of the trench containing the untreated silicon portion before the start of the etch process 100.

FIG. 3 shows a graph indicative of etch rate during a silicon selective etch process according to embodiments. The graph indicates vertical etched amounts measured linearly following a treatment using neat argon in a local plasma (solid line). The etched amount without a treatment is also shown (dashed line) for comparison. The hump in the solid line corresponds to the portion of silicon which has been treated (the treated silicon portion) and continuing the etch beyond fifty seconds results in an etch rate consistent with no treatment. Compound etches according to the invention operate in the region displaying the hump.

The process 100 depicted in FIG. 1 may be succinctly described as treat-etch sequences. More generally, treat-etch-treat-etch sequences and treat-etch-treat-etch-treat-etch sequences are also possible. Breaking up the etch process into multiple treat-etch cycles the etch process in the high etch rate portion (the hump) of the curve in FIG. 3. In other words, the process of operation 110 enables treatment of a certain depth of the silicon. Etching at operation 140 beyond the treated silicon portion will lower the effective etch rate of the combined process. Multiple cycles may be desirable to allow each cycle to avoid etching beyond the treated silicon portion.

The flow of the fluorine-containing precursor may further include one or more relatively inert gases such as He, N₂, Ar. The inert gas can be used to improve plasma stability, process uniformity and the like. Argon is helpful, as an additive, to promote the formation of a stable plasma, however, current experimentation has established that inclusion of argon results in a nonuniform (bumpy) post etch surface. Process uniformity is generally increased when helium is included. In one embodiment, helium does not cause the bumpiness associated with argon. These additives are present in embodiments throughout this specification. Flow rates and ratios of the different gases may be used to control etch rates and etch selectivity.

In embodiments, the fluorine-containing gas (e.g. NF₃) is supplied at a flow rate of between about 5 sccm (standard cubic centimeters per minute) and 400 sccm, He at a flow rate of between about 0 slm (standard liters per minute) and 3 slm, and N₂ at a flow rate of between about 0 slm and 3 slm. One of ordinary skill in the art would recognize that other gases and/or flows may be used depending on a number of factors including processing chamber configuration, substrate size, geometry and layout of features being etched, and the like. The temperature of the substrate may be between about −20° C. and about 200° C. during both the treatment and the etching process.

Additional process parameters are disclosed in the course of describing an exemplary processing chamber and system.

### Exemplary Processing System

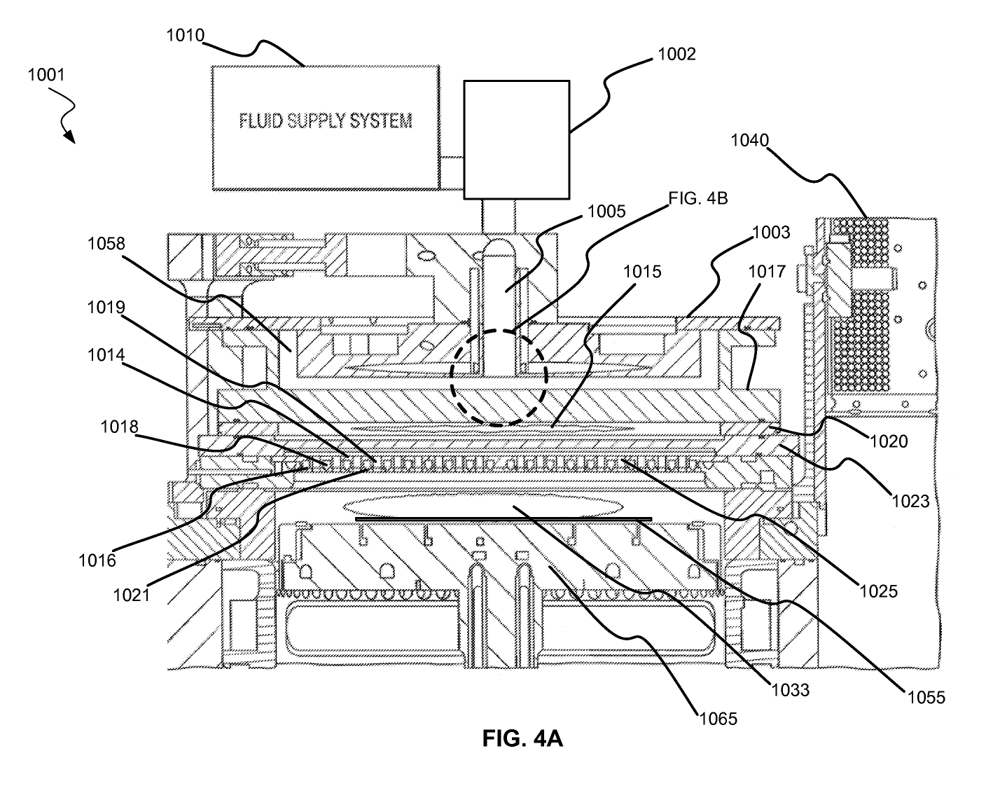

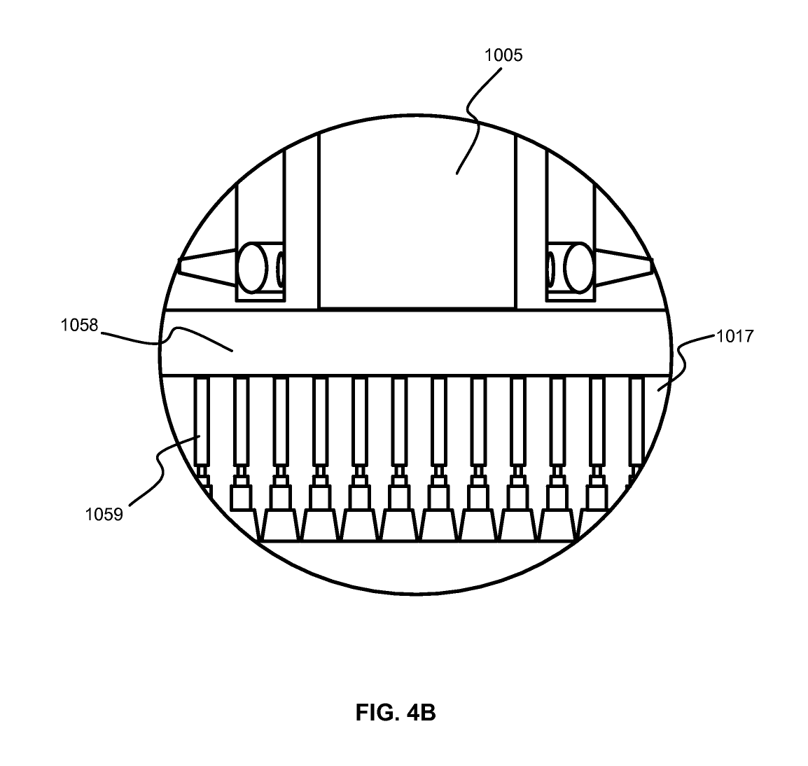

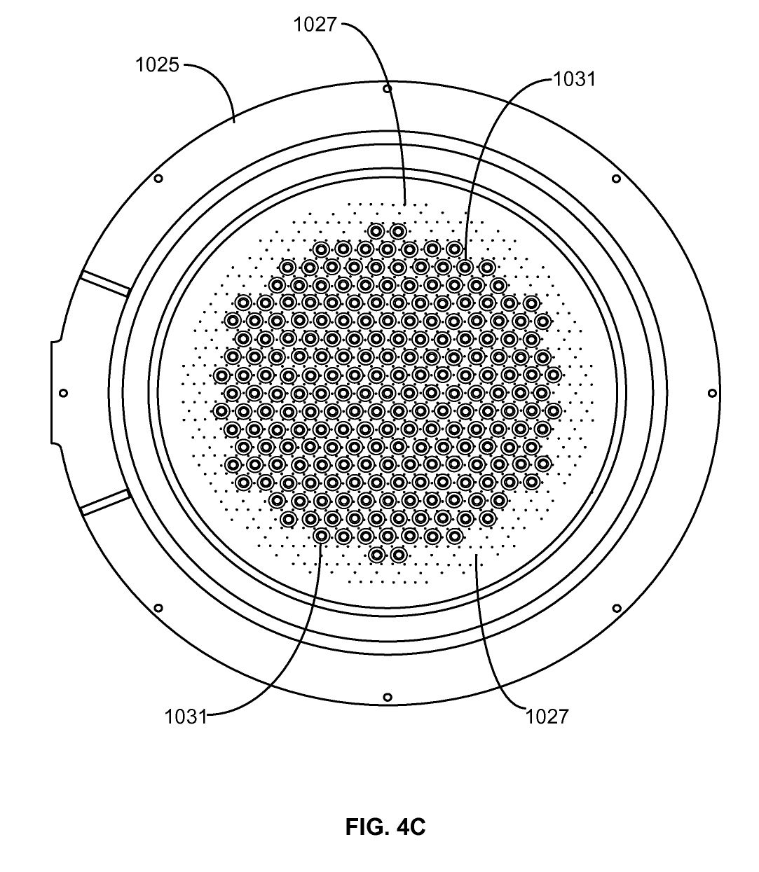

FIG. 4A shows a cross-sectional view of an exemplary substrate processing chamber 1001 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into chamber plasma region 1015 through a gas inlet assembly 1005. A remote plasma system (RPS) 1002 may optionally be included in the system, and may process a first gas which then travels through gas inlet assembly 1005. The inlet assembly 1005 may include two or more distinct gas supply channels where the second channel (not shown) may bypass the RPS 1002, if included. Accordingly, in embodiments the precursor gases may be delivered to the processing chamber in an unexcited state. In another example, the first channel provided through the RPS may be used for the process gas and the second channel bypassing the RPS may be used for a treatment gas in embodiments. The process gas may be excited within the RPS 1002 prior to entering the chamber plasma region 1015. Accordingly, the fluorine-containing precursor as discussed above, for example, may pass through RPS 1002 or bypass the RPS unit in embodiments. Various other examples encompassed by this arrangement will be similarly understood.

A cooling plate 1003, faceplate 1017, ion suppressor 1023, showerhead 1025, and a substrate support 1065 (also known as a pedestal), having a substrate 1055 disposed thereon, are shown and may each be included according to embodiments. The pedestal 1065 may have a heat exchange channel through which a heat exchange fluid flows to control the temperature of the substrate. This configuration may allow the substrate 1055 temperature to be cooled or heated to maintain relatively low temperatures, such as between about −20° C. to about 200° C., or therebetween. The heat exchange fluid may comprise ethylene glycol and/or water. The wafer support platter of the pedestal 1065, which may comprise aluminum, ceramic, or a combination thereof, may also be resistively heated to relatively high temperatures, such as from up to or about 100° C. to above or about 1100° C., using an embedded resistive heater element. The heating element may be formed within the pedestal as one or more loops, and an outer portion of the heater element may run adjacent to a perimeter of the support platter, while an inner portion runs on the path of a concentric circle having a smaller radius. The wiring to the heater element may pass through the stem of the pedestal 1065, which may be further configured to rotate.

The faceplate 1017 may be pyramidal, conical, or of another similar structure with a narrow top portion expanding to a wide bottom portion. The faceplate 1017 may additionally be flat as shown and include a plurality of through-channels used to distribute process gases. Plasma generating gases and/or plasma excited species, depending on use of the RPS 1002, may pass through a plurality of holes, shown in FIG. 4B, in faceplate 1017 for a more uniform delivery into the chamber plasma region 1015.

Exemplary configurations may include having the gas inlet assembly 1005 open into a gas supply region 1058 partitioned from the chamber plasma region 1015 by faceplate 1017 so that the gases/species flow through the holes in the faceplate 1017 into the chamber plasma region 1015. Structural and operational features may be selected to prevent significant backflow of plasma from the chamber plasma region 1015 back into the supply region 1058, gas inlet assembly 1005, and fluid supply system 1010. The structural features may include the selection of dimensions and cross-sectional geometries of the apertures in faceplate 1017 to deactivate back-streaming plasma. The operational features may include maintaining a pressure difference between the gas supply region 1058 and chamber plasma region 1015 that maintains a unidirectional flow of plasma through the showerhead 1025. The faceplate 1017, or a conductive top portion of the chamber, and showerhead 1025 are shown with an insulating ring 1020 located between the features, which allows an AC potential to be applied to the faceplate 1017 relative to showerhead 1025 and/or ion suppressor 1023. The insulating ring 1020 may be positioned between the faceplate 1017 and the showerhead 1025 and/or ion suppressor 1023 enabling a capacitively coupled plasma (CCP) to be formed in the first plasma region. A baffle (not shown) may additionally be located in the chamber plasma region 1015, or otherwise coupled with gas inlet assembly 1005, to affect the flow of fluid into the region through gas inlet assembly 1005.

The ion suppressor 1023 may comprise a plate or other geometry that defines a plurality of apertures throughout the structure that are configured to suppress the migration of ionically-charged species out of chamber plasma region 1015 while allowing uncharged neutral or radical species to pass through the ion suppressor 1023 into an activated gas delivery region between the suppressor and the showerhead. In embodiments, the ion suppressor 1023 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 1023 may provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., Si:SiN etch ratios, Si:SiO etch ratios, etc.

The plurality of holes in the ion suppressor 1023 may be configured to control the passage of the activated gas, i.e., the ionic, radical, and/or neutral species, through the ion suppressor 1023. For example, the aspect ratio of the holes, or the hole diameter to length, and/or the geometry of the holes may be controlled so that the flow of ionically-charged species in the activated gas passing through the ion suppressor 1023 is reduced. The holes in the ion suppressor 1023 may include a tapered portion that faces chamber plasma region 1015, and a cylindrical portion that faces the showerhead 1025. The cylindrical portion may be shaped and dimensioned to control the flow of ionic species passing to the showerhead 1025. An adjustable electrical bias may also be applied to the ion suppressor 1023 as an additional means to control the flow of ionic species through the suppressor.

The ion suppression element 1023 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate is not always the goal. In many instances, the etch rate of the remote plasma etch process increases when ionic species are able to reach the substrate. In these instances, the ion suppressor may help to control the concentration of ionic species in the reaction region at a level that assists the process.

Showerhead 1025 in combination with ion suppressor 1023 may allow a plasma present in chamber plasma region 1015 to avoid directly exciting gases in substrate processing region 1033, while still allowing excited species to travel from chamber plasma region 1015 into substrate processing region 1033. In this way, the chamber may be configured to prevent the plasma from contacting a substrate 1055 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which silicon oxide or silicon nitride etch may increase.

The processing system may further include a power supply 1040 electrically coupled with the processing chamber to provide electric power to the faceplate 1017, ion suppressor 1023, showerhead 1025, and/or pedestal 1065 to generate a plasma in the chamber plasma region 1015 or processing region 1033. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to chamber plasma region 1015. This in turn may allow development of particular plasma characteristics such that precursors may be dissociated in specific ways to enhance the etching profiles produced by these precursors.

A plasma may be ignited either in chamber plasma region 1015 above showerhead 1025 or substrate processing region 1033 below showerhead 1025. A plasma may be present in chamber plasma region 1015 to produce the radical-fluorine precursors from an inflow of the fluorine-containing precursor. An AC voltage typically in the radio frequency (RF) range may be applied between the conductive top portion of the processing chamber, such as faceplate 1017, and showerhead 1025 and/or ion suppressor 1023 to ignite a plasma in chamber plasma region 1015 during deposition. An RF power supply may generate a high RF frequency of 13.56 MHz but may also generate other frequencies alone or in combination with the 13.56 MHz frequency.

Plasma power can be of a variety of frequencies or a combination of multiple frequencies. In the exemplary processing system the plasma may be provided by RF power delivered to faceplate 1017 relative to ion suppressor 1023 and/or showerhead 1025. The RF power may be between about 10 watts and about 5000 watts, between about 100 watts and about 2000 watts, between about 200 watts and about 1500 watts, or between about 200 watts and about 1000 watts in embodiments. The RF frequency applied in the exemplary processing system may be low RF frequencies less than about 200 kHz, high RF frequencies between about 10 MHz and about 15 MHz, or microwave frequencies greater than or about 1 GHz in embodiments. The plasma power may be capacitively-coupled (CCP) or inductively-coupled (ICP) into the remote plasma region.

Chamber plasma region 1015 (top plasma in figure) may be left at low or no power when a bottom plasma in the substrate processing region 1033 is turned on to, for example, cure a film or clean the interior surfaces bordering substrate processing region 1033. A plasma in substrate processing region 1033 may be ignited by applying an AC voltage between showerhead 1025 and the pedestal 1065 or bottom of the chamber. A treatment gas (such as argon) may be introduced into substrate processing region 1033 while the plasma is present to facilitate treatment of the patterned substrate. The showerhead 1025 may also be biased at a positive DC voltage relative to the pedestal 1065 or bottom of the chamber to accelerate positively charged ions toward patterned substrate 1055. In embodiments, the local plasma in substrate processing region 1033 may be struck by applying AC power via an inductively-coupled source while applying DC power by capacitively coupled means. As indicated previously, the local plasma power may be between about 10 watts and about 500 watts, between about 20 watts and about 400 watts, between about 30 watts and about 300 watts, or between about 50 watts and about 200 watts in embodiments of the invention.

A fluid, such as a precursor, for example a fluorine-containing precursor, may be flowed into the processing region 1033 by embodiments of the showerhead described herein. Excited species derived from the process gas in chamber plasma region 1015 may travel through apertures in the ion suppressor 1023, and/or showerhead 1025 and react with an additional precursor flowing into the processing region 1033 from a separate portion of the showerhead. Alternatively, if all precursor species are being excited in chamber plasma region 1015, no additional precursors may be flowed through the separate portion of the showerhead. Little or no plasma may be present in the processing region 1033 during the remote plasma etch process. Excited derivatives of the precursors may combine in the region above the substrate and/or on the substrate to etch structures or remove species from the substrate.

Exciting the fluids in the chamber plasma region 1015 directly, or exciting the fluids in the RPS units 1002, may provide several benefits. The concentration of the excited species derived from the fluids may be increased within the processing region 1033 due to the plasma in the chamber plasma region 1015. This increase may result from the location of the plasma in the chamber plasma region 1015. The processing region 1033 may be located closer to the chamber plasma region 1015 than the remote plasma system (RPS) 1002, leaving less time for the excited species to leave excited states through collisions with other gas molecules, walls of the chamber, and surfaces of the showerhead.

The uniformity of the concentration of the excited species derived from the process gas may also be increased within the processing region 1033. This may result from the shape of the chamber plasma region 1015, which may be more similar to the shape of the processing region 1033. Excited species created in the RPS 1002 may travel greater distances to pass through apertures near the edges of the showerhead 1025 relative to species that pass through apertures near the center of the showerhead 1025. The greater distance may result in a reduced excitation of the excited species and, for example, may result in a slower growth rate near the edge of a substrate. Exciting the fluids in the chamber plasma region 1015 may mitigate this variation for the fluid flowed through RPS 1002, or alternatively bypassed around the RPS unit.

The processing gases may be excited in chamber plasma region 1015 and may be passed through the showerhead 1025 to the processing region 1033 in the excited state. While a plasma may be generated in the processing region 1033, a plasma may alternatively not be generated in the processing region. In one example, the only excitation of the processing gas or precursors may be from exciting the processing gases in chamber plasma region 1015 to react with one another in the processing region 1033. As previously discussed, this may be to protect the structures patterned on the substrate 1055.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In some embodiments the treatment gas may be used without a plasma. When the treatment gas includes water vapor, the delivery may be achieved using a mass flow meter (MFM), an injection valve, or by commercially available water vapor generators. The treatment gas may be introduced to the processing region 1033, either through the RPS unit or bypassing the RPS unit, and may further be excited in the first plasma region.

FIG. 4B shows a detailed view of the features affecting the processing gas distribution through faceplate 1017. As shown in FIG. 4A and FIG. 4B, faceplate 1017, cooling plate 1003, and gas inlet assembly 1005 intersect to define a gas supply region 1058 into which process gases may be delivered from gas inlet 1005. The gases may fill the gas supply region 1058 and flow to chamber plasma region 1015 through apertures 1059 in faceplate 1017. The apertures 1059 may be configured to direct flow in a substantially unidirectional manner such that process gases may flow into processing region 1033, but may be partially or fully prevented from backflow into the gas supply region 1058 after traversing the faceplate 1017.

The gas distribution assemblies such as showerhead 1025 for use in the processing chamber section 1001 may be referred to as dual channel showerheads (DCSH) and are additionally detailed in the embodiments described in FIG. 4A as well as FIG. 4C herein. The dual channel showerhead may provide for etching processes that allow for separation of etchants outside of the processing region 1033 to provide limited interaction with chamber components and each other prior to being delivered into the processing region.

The showerhead 1025 may comprise an upper plate 1014 and a lower plate 1016. The plates may be coupled with one another to define a volume 1018 between the plates. The coupling of the plates may be so as to provide first fluid channels 1019 through the upper and lower plates, and second fluid channels 1021 through the lower plate 1016. The formed channels may be configured to provide fluid access from the volume 1018 through the lower plate 1016 via second fluid channels 1021 alone, and the first fluid channels 1019 may be fluidly isolated from the volume 1018 between the plates and the second fluid channels 1021. The volume 1018 may be fluidly accessible through a side of the gas distribution assembly 1025. Although the exemplary system of FIGS. 4A-4C includes a dual-channel showerhead, it is understood that alternative distribution assemblies may be utilized that maintain first and second precursors fluidly isolated prior to the processing region 1033. For example, a perforated plate and tubes underneath the plate may be utilized, although other configurations may operate with reduced efficiency or not provide as uniform processing as the dual-channel showerhead as described.

In the embodiment shown, showerhead 1025 may distribute via first fluid channels 1019 process gases which contain plasma effluents upon excitation by a plasma in chamber plasma region 1015. In embodiments, the process gas introduced into the RPS 1002 and/or chamber plasma region 1015 may contain fluorine, e.g., CF₄, NF₃ or XeF₂. The process gas may also include a carrier gas such as helium, argon, nitrogen (N₂), etc. Plasma effluents may include ionized or neutral derivatives of the process gas and may also be referred to herein as a radical-fluorine precursor referring to the atomic constituent of the process gas introduced.

FIG. 4C is a bottom view of a showerhead 1025 for use with a processing chamber in embodiments. Showerhead 1025 corresponds with the showerhead shown in FIG. 4A. Through-holes 1031, which show a view of first fluid channels 1019, may have a plurality of shapes and configurations to control and affect the flow of precursors through the showerhead 1025. Small holes 1027, which show a view of second fluid channels 1021, may be distributed substantially evenly over the surface of the showerhead, even amongst the through-holes 1031, which may help to provide more even mixing of the precursors as they exit the showerhead than other configurations.

An additional dual channel showerhead, as well as this processing system and chamber, are more fully described in patent application Ser. No. 13/251,714 filed on Oct. 3, 2011, which is hereby incorporated by reference for all purposes to the extent not inconsistent with the claimed features and description herein.

The chamber plasma region 1015 or a region in an RPS may be referred to as a remote plasma region. In embodiments, the radical precursor, e.g., a radical-fluorine precursor, is created in the remote plasma region and travels into the substrate processing region where it may or may not combine with additional precursors. In embodiments, the additional precursors are excited only by the radical-fluorine precursor. Plasma power may essentially be applied only to the remote plasma region in embodiments to ensure that the radical-fluorine precursor provides the dominant excitation. Nitrogen trifluoride or another fluorine-containing precursor may be flowed into chamber plasma region 1015 at rates between about 5 sccm and about 500 sccm, between about 10 sccm and about 150 sccm, or between about 25 sccm and about 125 sccm in embodiments.

Combined flow rates of precursors into the chamber may account for 0.05% to about 20% by volume of the overall gas mixture; the remainder being carrier gases. The fluorine-containing precursor may be flowed into the remote plasma region, but the plasma effluents may have the same volumetric flow ratio in embodiments. In the case of the fluorine-containing precursor, a purge or carrier gas may be first initiated into the remote plasma region before the fluorine-containing gas to stabilize the pressure within the remote plasma region. Substrate processing region 1033 can be maintained at a variety of pressures during the flow of precursors, any carrier gases, and plasma effluents into substrate processing region 1033. The pressure may be maintained between about 0.1 mTorr and about 100 Torr, between about 1 Torr and about 20 Torr or between about 1 Torr and about 5 Torr in embodiments.

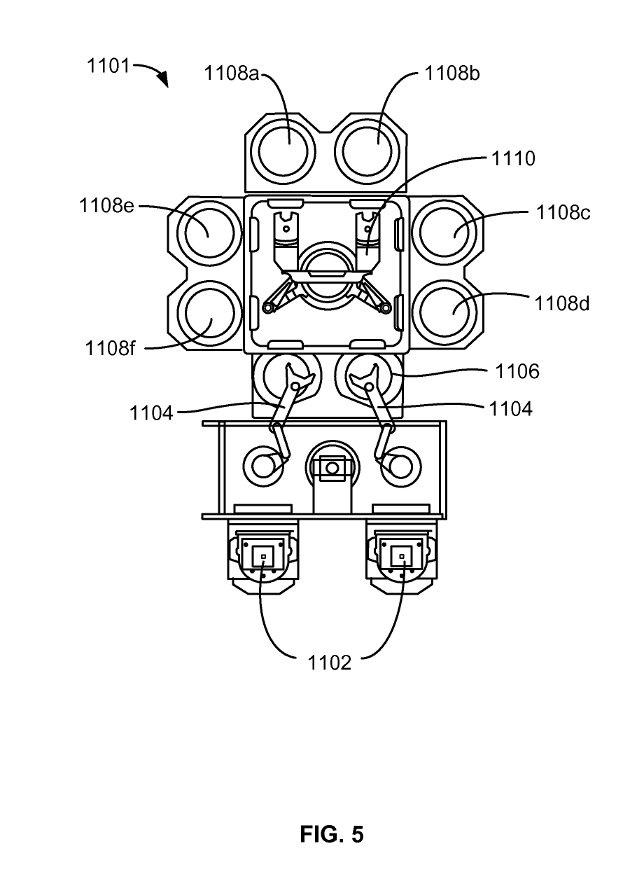

Embodiments of the deposition systems may be incorporated into larger fabrication systems for producing integrated circuit chips. FIG. 5 shows one such processing system 1101 of deposition, etching, baking, and curing chambers in embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 1108a-f may include one or more system components for depositing, annealing, curing and/or etching a dielectric film on the substrate wafer. In one configuration, two pairs of the processing chamber, e.g., 1108c-d and 1108e-f, may be used to deposit dielectric material on the substrate, and the third pair of processing chambers, e.g., 1108a-b, may be used to etch the deposited dielectric. In another configuration, all three pairs of chambers, e.g., 1108a-f, may be configured to etch a dielectric film on the substrate. Any one or more of the processes described may be carried out in chamber(s) separated from the fabrication system shown in embodiments.

In the preceding description, for the purposes of explanation, numerous details have been set forth to provide an understanding of various embodiments of the present invention. It will be apparent to one skilled in the art, however, that certain embodiments may be practiced without some of these details, or with additional details.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon” of the patterned substrate is predominantly Si but may include minority concentrations of other elemental constituents such as nitrogen, oxygen, hydrogen, carbon and the like. Exposed “silicon” may consist of or consist essentially of silicon. Exposed “silicon nitride” of the patterned substrate is predominantly Si₃N₄ but may include minority concentrations of other elemental constituents such as oxygen, hydrogen, carbon and the like. “Exposed silicon nitride” may consist essentially of or consist of silicon and nitrogen. Exposed “silicon oxide” of the patterned substrate is predominantly SiO₂ but may include minority concentrations of other elemental constituents such as nitrogen, hydrogen, carbon and the like. In embodiments, silicon oxide films etched using the methods taught herein consist essentially of or consist of silicon and oxygen.

The term “precursor” is used to refer to any process gas which takes part in a reaction to either remove material from or deposit material onto a surface. “Plasma effluents” describe gas exiting from the chamber plasma region and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” are radical precursors which contain fluorine but may contain other elemental constituents. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well known processes and elements have not been described to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of etching a patterned substrate the method comprising:
treating the patterned substrate with a local plasma formed from an inert gas, wherein treating the patterned substrate comprises treating an untreated substrate portion to form a treated substrate portion; and wherein the local plasma is formed by applying a local plasma power to excite the local plasma; and
etching the treated substrate portion, wherein etching the treated substrate portion comprises flowing plasma effluents into a substrate processing region housing the patterned substrate after treatment, wherein the plasma effluents are formed by flowing a fluorine-containing precursor into a remote plasma region fluidly coupled to the substrate processing region while forming a remote plasma in the remote plasma region to produce the plasma effluents, wherein forming the remote plasma in the remote plasma region to produce the plasma effluents comprises applying an RF plasma having an RF plasma power to the remote plasma region.

2. The method of claim 1 wherein the local plasma comprises argon.

3. The method of claim 1 wherein the local plasma power is between about 10 watts and about 500 watts to the substrate processing region.

4. The method of claim 1 wherein RF plasma power is between about 300 watts and about 5000 watts to the remote plasma region.

5. The method of claim 1 wherein the local plasma is formed by applying a DC bias power such that the local plasma power comprises both an AC portion and a DC portion.

6. The method of claim 1 wherein the DC bias power comprises applying a DC bias voltage greater than 400 volts to accelerate inert gas ions toward the patterned substrate.

7. The method of claim 1 wherein the plasma effluents enter the substrate processing region through through-holes in a showerhead, and wherein the showerhead separates the remote plasma region from the substrate processing region.

8. The method of claim 1 wherein the local plasma consists essentially of inert gases.

9. The method of claim 1 wherein the local plasma consists essentially of argon.

10. A method of etching a patterned substrate the method comprising:
treating the patterned substrate with a local plasma formed from an inert gas, wherein treating the patterned substrate comprises treating an untreated silicon portion to form a treated silicon portion; and wherein the local plasma is formed by applying a local plasma power;
flowing a fluorine-containing precursor into a remote plasma region fluidly coupled to a substrate processing region while forming a remote plasma in the remote plasma region to produce plasma effluents, wherein forming the remote plasma in the remote plasma region to produce the plasma effluents comprises applying an RF plasma having an RF plasma power to the plasma region; and
etching the treated silicon portion by flowing the plasma effluents into the substrate processing region.

11. The method of claim 10 wherein the remote plasma region is devoid of hydrogen during the operation of flowing the fluorine-containing precursor.

12. The method of claim 10 wherein the untreated silicon portion is single crystal silicon.

13. The method of claim 10 wherein the fluorine-containing precursor comprises at least one of nitrogen trifluoride, carbon tetrafluoride or sulfur hexafluoride.

14. The method of claim 10 wherein the local plasma is a capacitively-coupled plasma.

15. The method of claim 10 wherein the patterned substrate comprises silicon nitride on both sides of a trench containing the untreated silicon portion before the method begins.
